(19) United States
(12) Patent Application Publication
(10) Pub. No.: US 2020/0167638 A1
(43) Pub. Date: May 28, 2020

(54) CIRCUIT NEURONAL APTE À METTRE EN OEUVRE UN APPRENTISSAGE SYNAPTIQUE

(71) Applicant: COMMISSARIAT À L'ÉNERGIE ATOMIQUE ET AUX ÉNERGIES ALTERNATIVES, Paris (FR)

(72) Inventors: François Rummens, Grenoble Cedex 09 (FR); Alexandre Valentian, Grenoble Cedex 09 (FR)

(21) Appl. No.: 16/695,588

(22) Filed: Nov. 26, 2019

(30) Foreign Application Priority Data
Nov. 27, 2018 (FR) 1871944

(51) Int. Cl. G06N 3/063; G06N 3/08; G11C 13/00

(52) U.S. Cl. CPC G06N 3/063; G11C 13/0019; G06N 3/08

(57) ABSTRACT

A synaptic integration circuit for a neuromorphic chip comprising a resistive memory synapse which has an activation terminal to receive a presynaptic action signal and a propagation terminal intended to be connected to the circuit for transmitting a synaptic output signal which depends on the resistance of the memory. The circuit comprises an accumulator of the synaptic output signal, a comparator configured to emit a postsynaptic spike in case of the crossing of a threshold (Vm) by the accumulated output signal. It further comprises a control unit configured, when a presynaptic action signal is applied on the activation terminal, to impose a conductance modification voltage on the synapse by controlling the application of a postsynaptic action signal (V_{BL}_{ₛₑₜ}, V_{BL}_{ᵣₑₛₑₜ}) on the propagation terminal.

### TECHNICAL FIELD

The field of the invention is that of neuromorphic chips with artificial neuron networks that make use of resistive memory synapses. The invention more particularly relates to the learning carried out directly on a chip of such a network of neurons.

### PRIOR ART

A nerve cell, or neuron, can be broken down into several parts:
The dendrites which are the inputs of the neuron via which it receives excitation or inhibition signals;
The body of the neuron which is the theatre for ionic exchanges through the cell membrane;
The axon, a long extension of the cell body, which is the sole output of the body.

According to the excitation or inhibition signals received on the dendrites, ions transit through the cell membrane. The imbalance in charges between the inside and the outside of the cell induces a difference in voltage on either side of the membrane. This is then referred to as membrane voltage at the terminals of a membrane capacitance. When this membrane voltage exceeds a certain level, i.e. when the cell is sufficiently excited, the neuron experiences a brutal exchange of ions. This results in a significant variation in the membrane voltage. This variation, called “action potential” or “spike”, propagates along the axon, to the synaptic buttons which form the outputs of the neuron. Seen from outside the cell, these “spikes” form the electrical activity of the neuron.

In a network of biological neurons, each neuron is connected to several thousand others via as many synapses. The term synapse designates the connection between the axon terminal of so-called presynaptic neuron and a dendrite of a so-called postsynaptic neuron. The influence of the presynaptic neuron on the postsynaptic neuron is weighted by the weight of the synapse which can be excitatory or inhibitory. In the first case, a presynaptic spike charges the membrane voltage of the postsynaptic neuron and precipitates the generating of a postsynaptic spike. In the second case, a presynaptic spike has for effect to depolarise the postsynaptic membrane and to delay the appearance of a postsynaptic spike.

Artificial neuron networks are used in various fields of signal processing (visual, audio or other) such as for example in the field of data classification, image recognition or decision making. They are inspired by the networks of biological neurons of which they imitate the operation and are substantially comprised of artificial neurons that are connected together by synapses, which are conventionally implemented by digital memories, but which can also be implemented by resistive components of which the conductance varies according to the voltage applied at the terminals thereof.

Before being functional, such a neuron network must go through a learning phase that consists in adjusting the weight of the synapses according to the inputs of the network so that the network associates the desired outputs with it. A possible learning strategy is a strategy carried out by the network itself (this is referred to as “on-chip” learning) and is carried out in an unsupervised manner in that the inputs sent to the network are not labelled, with the network itself determining to which class which input belongs to in order to associate a neuron of the output layer with each class.

A conventional implementation of unsupervised learning is based on pulse neurons (also called “action potential neuron” or “spiking neuron”). The simplest model of a spiking neuron is of the “Integrate and Fire” type: it integrates its inputs, compares the result of this integration with a threshold and emits a spike when this threshold is crossed while still discharging the membrane voltage.

A possible learning law is a law referred to “Spike Timing Dependent Plasticity” (STDP law) according to which each synapse adjusts its weight according to the relative occurrences between the pre- and postsynaptic spikes. If a presynaptic spike is followed by a postsynaptic spike, the law assumes a causal link to be maintained and reinforces the synapse by increasing its weight. On the contrary, if a postsynaptic spike appears shortly before a post presynaptic, the synaptic weight must be decreased. In both cases, the shorter the time is between the pre- and postsynaptic spikes, the larger the modification in the weight is.

Another possible learning law is the one referred to as “Spike-Driven Synaptic Plasticity” law (SDSP law) which has the interest of not having to monitor a time difference per synapse as is the case for the STDP law. According to the SDSP law, at each presynaptic spike received, each synapse polls the state of the postsynaptic neuron and adapts its weigh in consequence. If the membrane voltage of this postsynaptic neuron is close to the threshold, it is deduced that the presynaptic spike has a good chance of triggering the emission of a spike and therefore that the presynaptic neuron that emitted this spike has a substantial effect on the postsynaptic neuron. The synaptic connection is then reinforced by increasing the weight of the synapse (this is referred to as LTP for “Long Term Potentiation”). Otherwise, i.e. if the postsynaptic membrane voltage is close to zero, the weight is decreased (“Long Term Depression”, or LTD).

In order to prevent the synaptic weights from being modified at every presynaptic spike, a second rule limits the learning. The average activity of each neuron is estimated thanks to a variable, the concentration in calcium ions. This concentration increases when the neuron emits a spike and decreases otherwise. The potentiation or the depression of a synapse is then carried out or not according to the level of calcium of the postsynaptic neuron thereof.

Finally, the synapses used for SDSP learning are bistable synapses that can have several values, but of which only two of its values are stable, P_{MIN} and P_{MAX}. This instability results in the following behaviour. Any synaptic weight less than a value Pₘ located between P_{MIN} and P_{MAX} sees its weight slowly decrease to P_{MIN} and, inversely, any synaptic weight greater than Pₘ undergoes a gradual potentiation. At the end of learning, all of the synaptic weights are therefore either P_{MIN} or P_{MAX}.

Through their high density and their non-volatile nature, memristors or RRAM are ideal candidates for the implementation of synapses. The variable resistance of these devices can be increased (operation referred to as Reset) or decreased (Set operation) if relatively high electrical magnitudes (voltage and/or current) are applied thereto. If it is simply desired to read the value of their resistance without modifying it (Read operation), relatively low electrical magnitudes must be applied.

The integration of resistive synapses often takes the form of a memory plane, that is named a “synaptic plane”, in which the synapses are arranged in a network with transversal lines and columns. Each synapse has an activation terminal of the synapse and a propagation terminal of the synaptic signal. The activation terminals of the synapses of the same line are connected together by the intermediary of a Word-Line, and the propagation terminals of the synapses of the same column are connected together and connected to a synaptic integration circuit (an artificial neuron of the integrate and fire type) by the intermediary of a Bit-Line. A Word-Line is used to inject a voltage spike into the synapses of the corresponding line and the Bit-Lines are the outputs of these synapses. In the presence of a presynaptic activation on a Word-Line, each Bit-Line propagates a current weighted by the value of the corresponding resistive memory.

Such a synaptic plane thus makes it possible to connect an input layer of neurons (the presynaptic neurons) and an output layer of neurons (the postsynaptic neurons). An input neuron stimulates a line of synapses during the emission of a presynaptic spike via a Word-Line, and each one of the output neurons integrates the synaptic stimulation weighted by the value of the resistive memory to which it is connected via a Bit-Line.

As shown in FIG. 1, a resistive memory synapse generally has the form of a 1T1R cell comprised of a variable resistor M and of an access transistor T used to adjust the write currents and of which the gate forms the activation terminal of the synapse. FIG. 1 shows an example of a synaptic plane with 1T1R cells comprising three Word-Lines WL1-WL3, eight Bit-Lines BL1-BL8 with each one intended to be connected to an output neuron and a Source-Line (SL) connected to all of the synapses. The presence of a transistor per synapse limits the density of such a synaptic plane.

As shown in FIG. 2, it is possible to alternatively have recourse to 1S1R cells comprised of a variable resistor M and of a selector S that has a behaviour that is similar to a diode, even to two anti-parallel diodes. Each 1S1R cell is a dipole of which the terminals form the activation and propagation terminals, and the synaptic plane is organised as shown in FIG. 2 where the example was taken of a plane comprising three Word-Lines WL1-WL3 and four Bit-Lines BL1-BL4, and wherein each synapse is taken between a voltage on the corresponding Word-Line and a voltage on the corresponding Bit-Line thereof.

A solution is known in document WO 2016/067139 A1 for carrying out a learning of the STDP type. This solution however requires densifying the structure of each one of the resistive memory synapses and complicates the synaptic plane by requiring that each postsynaptic neuron be connected to the synapses of a column not only by a Bit-Line connected to the propagation terminals of the synapses but also by an additional Bit-Line connected to a third access terminal of the synapses in addition to the activation and propagation terminals.

### DISCLOSURE OF THE INVENTION

The invention has for objective to propose a less complex solution for carrying out the learning of the synapses that connect two successive layers of neurons. It proposes for this a synaptic integration circuit for a neuromorphic chip comprising a resistive memory synapse which has an activation terminal to receive a presynaptic action signal and a propagation terminal intended to be connected to said circuit for transmitting a synaptic output signal which depends on the resistance of said memory. The circuit comprises an accumulator of the synaptic output signal, a comparator configured to emit a postsynaptic spike in case of the crossing of a threshold by the accumulated output signal. This circuit further comprises a control unit configured, when a presynaptic action signal is applied on the activation terminal, to impose a conductance modification voltage on the synapse by controlling the application of a postsynaptic action signal on the propagation terminal.

Certain preferred but not limiting aspects of this circuit are the following:
it comprises a switchable connector configured to connect the accumulator to the propagation terminal when a read pulse of the presynaptic action signal is applied on the activation terminal;
the switchable connector is configured to disconnect the accumulator from the propagation terminal when a write pulse of the presynaptic action signal is applied on the activation terminal;
the control unit is furthermore configured, when the read pulse of the presynaptic action signal is applied on the activation terminal, to impose a read voltage on the synapse by controlling the application of a postsynaptic read signal on the propagation terminal;
it comprises an operational amplifier mounted as a follower in order to generate the postsynaptic read signal applied to the propagation terminal;
the control unit is furthermore configured, when the presynaptic action signal is applied on the activation terminal, to impose a read voltage on the synapse by controlling the application of a postsynaptic read signal on the propagation terminal;
it comprises an operational amplifier mounted as a follower which is used to selectively generate the postsynaptic read signal or the postsynaptic action signal;
it comprises a current step-down device that is inserted between the propagation terminal and the accumulator and which is activated when the circuit imposes a conductance modification voltage on the synapse;
the control unit is configured to control the application of the postsynaptic action signal on the propagation terminal in accordance with a learning logic of the spike-driven synaptic plasticity type;
the postsynaptic action signal is one of a potentiation signal and of a depression signal.

### BRIEF DESCRIPTION OF THE DRAWINGS

Other aspects, purposes, advantages and characteristics of the invention shall appear better when reading the following detailed description of preferred embodiments of the latter, given as a non-limiting example, and in reference to the drawings wherein, in addition to FIGS. 1 and 2 that have already been discussed hereinabove,

FIGS. 3 and 4 show the adjustment of the bus voltage carried out by circuits in accordance with the invention for the purposes of reading or writing a resistive memory;

FIGS. 5 to 8 are diagrams that show various embodiments of a circuit according to the invention.

### DETAILED DISCLOSURE OF PARTICULAR EMBODIMENTS

The invention has for framework a synaptic plane such as described hereinabove wherein the presynaptic spikes are injected one after the other on the corresponding Word-Line thereof. At each presynaptic spike of a neuron of the input layer, a complete line of synapses is activated and all of the neurons of the output layer are stimulated via the corresponding Bit-Line thereof according to the weight of the synapse that corresponds to them and which corresponds to the activated Word-Line.

During the learning, preferentially but not exclusively of the SDSP type, the weight of each synapse can be updated. With a learning of the SDSP type, such an update (i.e. a potentiation or a depression) is or is not produced according to solely the state of the postsynaptic neuron (its membrane voltage and its level of calcium).

Within the framework of the invention, the synapses are resistive memory synapses of the 1T1R or 1S1R type. In a possible implementation, the memories of the synapses are unipolar, multivalue and cumulative write RRAM memories. This means that the voltages and currents required for the various actions (Set, Reset, Read) are applied with the same polarity, that the resistance of the memories can have a complete range of values and that successive writes of the same type (Set or Reset) progressively shift the resistance of the memory in the desired direction. An example of such a memory is PCM (Phase Change Memory). Note that PCM memory is subjected to an offset effect such that a memory that has a substantial resistance value sees the latter increased and that, to a lesser degree, a memory that has a low resistance value sees the latter decrease.

The invention is not however limited to such memories, and thus extends to synapses that do not make use of multivalue memory but are comprised of several binary memories in parallel. Write accesses (Set, Reset) to the synapse impose in this case a voltage on the memories that forms the synapse such that certain memories change state and others do not. The invention also extends to synapses that make use of bipolar memories and in such a case a voltage is provided on the Source-Line (or on a Word-Line in the case of 1S1R cells) in the middle of the voltage range and voltages on the Bit-Lines that can be greater than or less than the aforementioned voltage.

The example is taken in what follows of PCM memories for which a voltage V_{read} makes it possible to make a read without modifying the resistance, a voltage Vₛₑₜ makes it possible to reduce the value of the resistance and a voltage Vᵣₑₛₑₜ makes it possible to increase the value of the resistance. By way of example, a supply voltage V_{DD}=1.8 V can be provided, and the following access voltages to a resistive memory: Vₛₑₜ=1.6 V, Vᵣₑₛₑₜ=1.2 V and V_{read}=0.4 V.

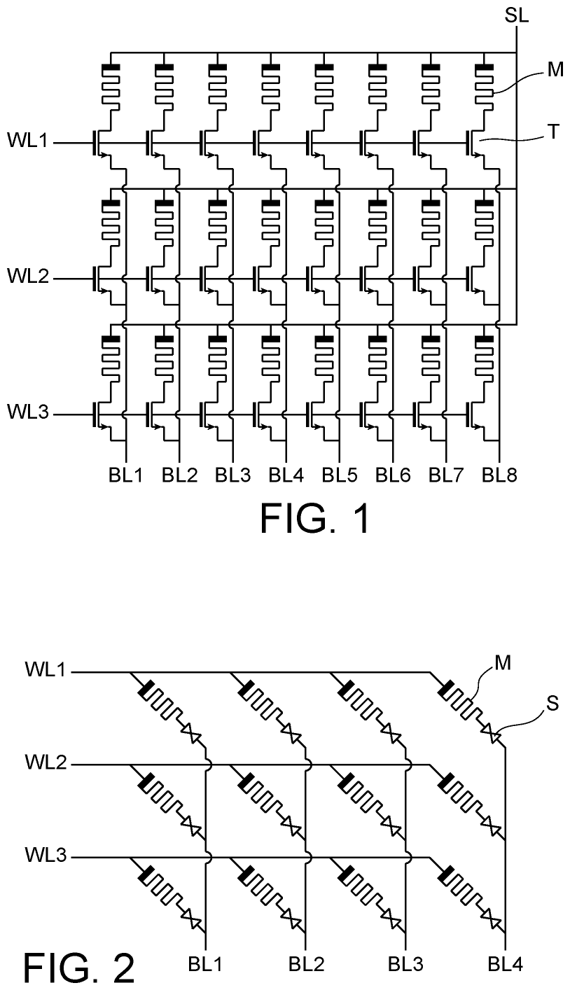

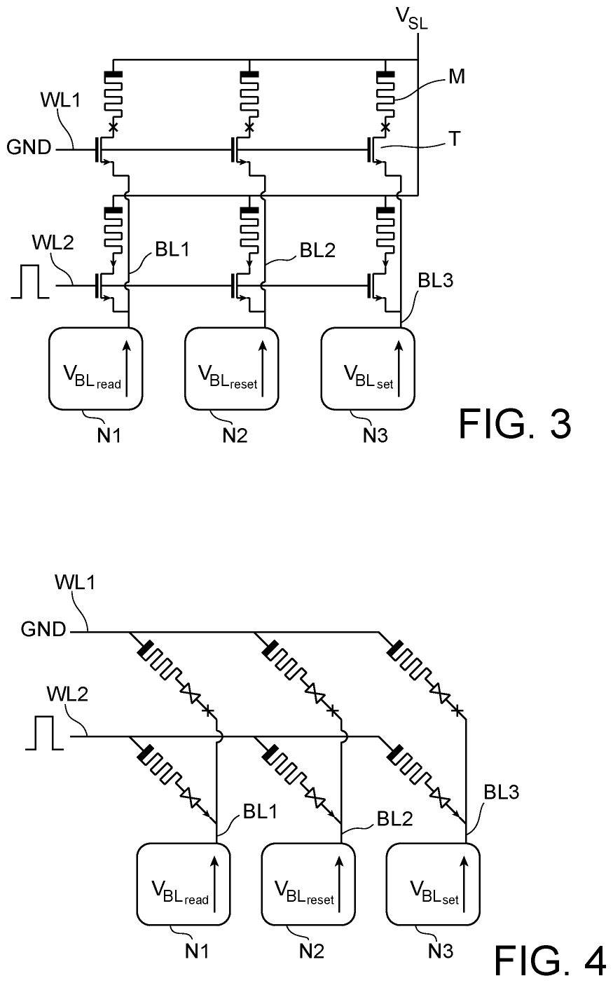

With the synaptic plane described hereinabove, the propagation terminal of each synapse is connected to its postsynaptic neuron via a Bit-Line. Thus, during the processing of a presynaptic spike, the synapse is taken between a voltage common to all of the synapses of the line (the voltage of the Source-Line in the case of a 1T1R cell, the voltage of the Word-Line for a 1S1R cell) and a voltage that is proper to its column, therefore to its postsynaptic neuron. Taking the example of FIGS. 3 and 4 wherein the Word-Line WL2 is activated, the synapse of the column i has at its terminals a difference in potential equal to V_{SL}− V_{BL}_{ᵢ} in the case of a 1T1R cell (FIG. 3) and equal to V_{WL2}−V_{BL}_{ᵢ} in the case of a 1S1R cell (FIG. 4). The invention proposes that at each presynaptic spike, each output neuron N1-N3 imposes on the Bit-Line BL1-BL3 thereof a voltage that makes it possible to perform a Set, a Reset or a Read. FIGS. 3 and 4 show an example in which:
the neuron N1 imposes on the Bit-Line BL1 a voltage V_{BL}_{_{read}} such that V_{SL}−V_{BL}_{_{read}}=V_{read} (FIG. 3) or V_{WL2}−V_{BL}_{_{read}}=V_{read} (FIG. 4) in order to carry out a Read;
the neuron N2 imposes on the Bit-Line BL2 a voltage V_{BL}_{ᵣₑₛₑₜ} such that V_{SL}−V_{BL}_{ᵣₑₛₑₜ}=Vᵣₑₛₑₜ (FIG. 3) or V_{WL2}−V_{BL}_{ᵣₑₛₑₜ}=Vᵣₑₛₑₜ (FIG. 4) in order to carry out a Reset; and
the neuron N3 imposes on the Bit-Line BL3 a voltage V_{BL}_{ₛₑₜ} such that V_{SL}−V_{BL}_{ₛₑₜ}=Vₛₑₜ (FIG. 3) or V_{WL2}−V_{BL}_{ₛₑₜ}=Vₛₑₜ (FIG. 4) in order to carry out a Set.

The invention thus makes it possible to carry out a learning continuously of the integration of the synaptic weights and this at the same time for all of the synapses of the activated line. This learning is furthermore applied on the synaptic plane by being managed locally by the neurons, not by the synapses which are much more numerous.

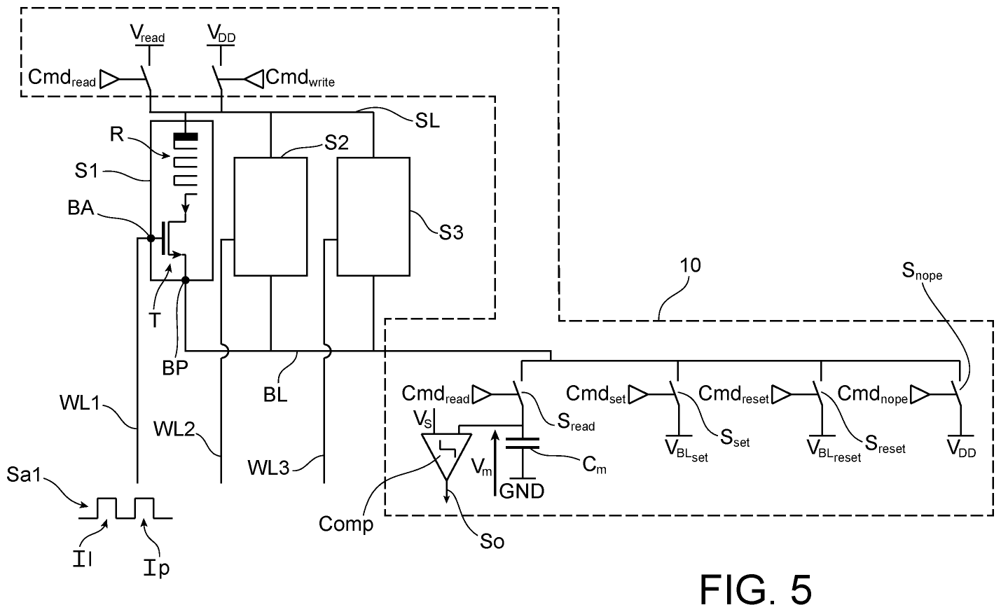

In reference to FIGS. 5 to 8, the invention relates more particularly to an artificial neuron that takes the form of a synaptic integration circuit 10, 20, 30, 40 for a neuromorphic chip. The chip comprises a resistive memory synapse S1, S2, S3 which has an activation terminal B_{A} to receive a presynaptic action signal Sa1, Sa2, Sa3, Sa4 and a propagation terminal B_{P} intended to be connected to said circuit for transmitting a synaptic output signal which depends on the resistance of said memory.

FIGS. 5 to 8 show three synapses S1, S2 and S3 that belong to three lines of a synaptic plane and for which the activation terminal B_{A} is respectively connected to a Word-Line WL1, WL2 and WL3. These synapses belong to the same column, and the propagation terminals B_{P} thereof are connected to the synaptic integration circuit 10, 20, 30, 40 via a Bit-Line BL. In these figures, a presynaptic action signal Sa1, Sa2, Sa3, Sa4 is applied on the Word-Line WL1 following the emission of a presynaptic spike by an input neuron associated with this Word-Line, activating the synapse S1. In these figures, GND designates the ground and V_{DD} the supply voltage.

In FIGS. 5, 7 and 8, the synapses are 1T1R cells. The activation terminal B_{A} of a synapse is connected to the gate of the transistor T and the propagation terminal B_{P} thereof is connected to the source of the transistor. The resistor M is taken between a signal line SL and the drain of the transistor T. The signal line SL can be common to all of the synapses of the plan or be associated only with the synapses of one or several lines of the plane, the latter therefore including several signal lines. In the FIG. 5, the signal line is common to the three lines shown.

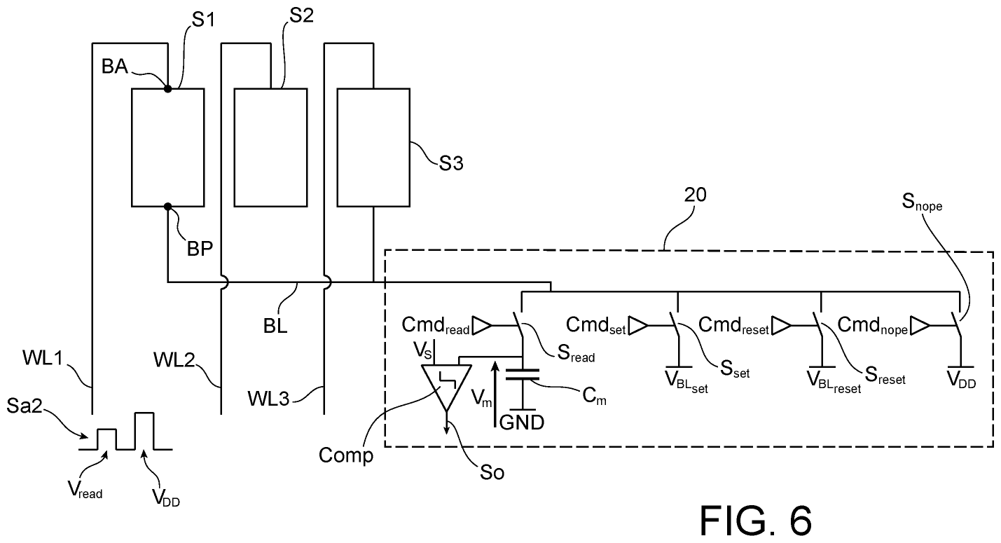

In FIG. 6, the synapses are 1S1R cells that each have two poles that form the activation and propagation terminals of the synapse.

The synaptic integration circuit 10, 20, 30, 40 comprises an accumulator Cm of the synaptic output signal and a comparator Comp configured to emit a postsynaptic spike So in case of the crossing of a threshold Vs by the accumulated output signal Vm which represents the membrane voltage of the neuron. The accumulator Cm is symbolised in the figures by a simple capacitor, but it can have a more complex form.

The circuit according to the invention is furthermore configured, when a presynaptic action signal is applied on the activation terminal B_{A} of the synapse S1, to impose a conductance modification voltage on the synapse S1 by applying a postsynaptic action signal on the propagation terminal B_{P} of the synapse S1 via the Bit-Line BL. The postsynaptic action can be one of a potentiation signal and a depression signal, with the circuit being configured to adjust the voltage on the Bit-Line to:
a voltage V_{BL}_{ᵣₑₛₑₜ} able itself to impose on the synapse S1 a conductance reduction voltage Vᵣₑₛₑₜ; or
a voltage V_{BL}_{ₛₑₜ} able itself to impose on the synapse S1 a conductance increase voltage Vₛₑₜ.

The circuit according to the invention has a control unit (not shown) configured to control the application of the postsynaptic action signal on the propagation terminal in accordance with a learning logic. According to this logic, the control unit can also be configured, when a presynaptic action signal is applied on the activation terminal B_{A} of the synapse S1, to impose on the propagation terminal B_{P} of the synapse S1 via the Bit-Line BL a neutral signal that does not induce any modification in the conductance of the synapse. The learning logic can be of the STDP type, in such a way that the postsynaptic action signal is or is not applied according to the relative occurrences of the presynaptic spike and of a postsynaptic spike. The learning logic is preferably of the SDSP type, the control unit then only evaluates the state of the neuron, and more particularly its membrane voltage Vm (which is already evaluated in order to determine whether or not the neuron has to emit a spike) and its concentration in calcium ions (which can be evaluated via a simple counting of the number of spikes emitted), in order to decide whether or not to modify the conductance of the synapse.

It was seen hereinabove that the presynaptic action signal Sa1, Sa2, Sa3, Sa4 is applied on the Word-Line WL1 following the emission of a presynaptic spike by the input neuron associated with this Word-Line.

In a first embodiment shown in FIGS. 5, 6 and 7, following the emission of the presynaptic spike, a presynaptic action signal Sa1, Sa2, Sa3 that has two successive spikes, referred to respectively as read pulse and write pulse of the presynaptic action signal, is imposed on the Word-Line WL1 and which will respectively make it possible to provide a Read operation (integration of the presynaptic spike) and a Set or Reset write operation (modification of the conductance). The read pulse can precede the write pulse, in such a way that the state of the neuron is affected by the read and the decision whether or not to write is made according to this new state for a SDSP learning. Alternatively, the write pulse can precede the read pulse, in which case the contribution of the presynaptic spike will use during this read the weight refreshed by this same pulse during the write. In an alternative embodiment, the state of the postsynaptic neuron is polled firstly and the decision whether or not to modify the conductance is saved in a local memory. Then a read is taken and finally a write according to that is written in the local memory. In another alternative embodiment, the presynaptic action signal can comprise three successive spikes that will make it possible to provide a Read operation, a Set write operation and a Reset write operation. This alternative can be advantageous for carrying out such operations on bipolar memories.

In FIGS. 5, 6 and 7, the circuit 10, 20, 30 comprises a connector S_{read} that can be switched via a read command Cmd_{read} applied by the control unit to connect the accumulator Cm to the propagation terminal B_{P} when the read pulse of the presynaptic action signal is applied on the activation terminal. The synaptic output signal which depends on the resistance of the memory can thus be accumulated.

This same connector S_{read} can furthermore be switched via the read command Cmd_{read} to disconnect the accumulator from the propagation terminal when the write pulse of the presynaptic action signal is applied on the activation terminal.

And when this write pulse of the presynaptic action signal is applied on the activation terminal, a conductance modification voltage is imposed on the synapse S1 by applying a postsynaptic action signal on the propagation terminal. According to the type of operation that has to be carried out in the framework of the learning (Set, Reset or no modification of the conductance), the Bit-Line BL is imposed with (by means of a connector Sₛₑₜ, Sᵣₑₛₑₜ or Sₙₒₚₑ which can be switched via a command Cmdₛₑₜ, Cmdᵣₑₛₑₜ or Cmdₙₒₚₑ applied by the control unit), a postsynaptic action signal which has one of the voltages from among the voltage V_{BL}_{ₛₑₜ} and the voltage V_{BL}_{ᵣₑₛₑₜ} or a neutral signal that has the supply voltage V_{DD}.

In the FIG. 5, 1T1R cells and a binary Source-Line voltage SL (i.e. variable between two voltage levels) are used. The voltage of the Source-Line SL is positioned, via the read command Cmd_{read} of the control unit, at the read voltage V_{read} when the read pulse II of the presynaptic action signal Sa1 is applied on the activation terminal. It is positioned, via a write command Cmd_{write} of the control unit, to the supply voltage V_{DD} when the write pulse Iₚ of the presynaptic action signal Sa1 is applied on the activation terminal. With the adjustment of the voltage of the Bit-Line BL to one among the voltages V_{BL}_{ᵣₑₛₑₜ}, V_{BL}_{ₛₑₜ} and V_{DD}, the voltage at the terminals of the synapse S1 are then respectively established at the conductance decrease voltage Vᵣₑₛₑₜ, the conductance increase voltage Vₛₑₜ or at 0 V.

In the FIG. 6, 1S1R cells and the same type of commands Cmd_{read}, Cmdₛₑₜ Cmdᵣₑₛₑₜ and Cmdₙₒₚₑ are used. The read pulse of the presynaptic action signal Sa2 is at the read voltage V_{read} and the write pulse of the presynaptic action signal Sa2 is at the supply voltage V_{DD}. Thus when the read pulse of the presynaptic action signal Sa2 is applied to the activation terminal, the voltage at the terminals of the synapse S1 is established at the read voltage V_{read}. And when the write pulse of the presynaptic action signal Sa2 is applied to the activation terminal, the voltage of the Bit-Line BL is adjusted to one among the voltages V_{BL}_{ᵣₑₛₑₜ}, V_{BL}_{ₛₑₜ} and V_{DD}, with the voltage at the terminals of the synapse S1 then being established respectively at the conductance decrease voltage Vᵣₑₛₑₜ, the conductance increase voltage Vₛₑₜ or at 0 V.

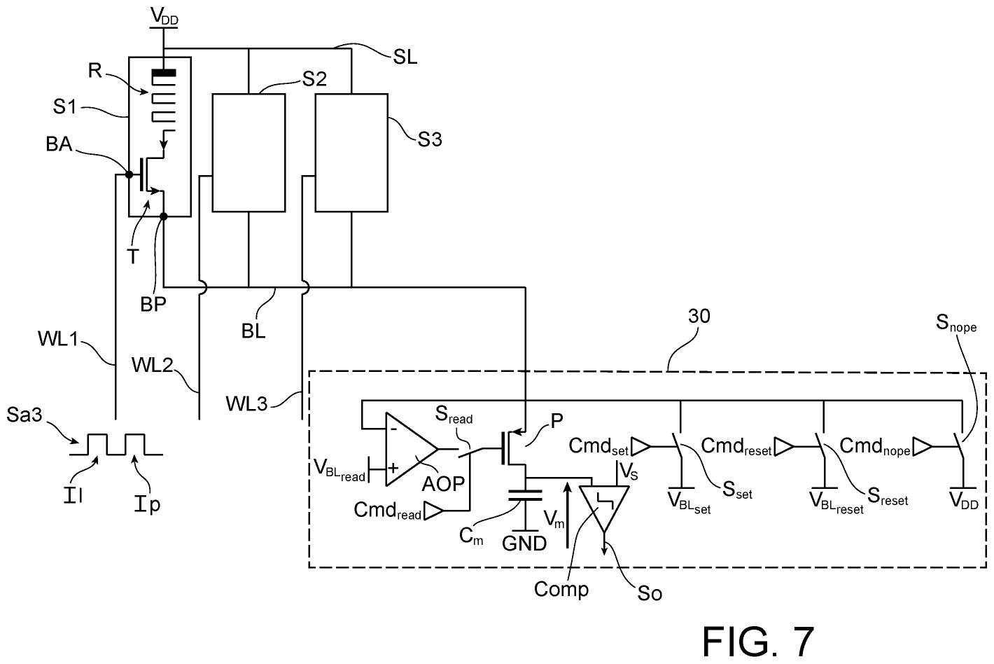

In the FIG. 7, 1T1R cells, the same type of commands Cmd_{read}, Cmdₛₑₜ, Cmdᵣₑₛₑₜ and Cmdₙₒₚₑ and a voltage of the Source-Line SL fixed to the supply voltage V_{DD} are used which makes it possible to avoid, compared to the solution of FIG. 5, having to charge and discharge the Source-Line at every presynaptic spike. When the read pulse II of the presynaptic action signal Sa3 is applied on the activation terminal, the circuit 30 imposes the read voltage V_{read} on the synapse by applying a postsynaptic read signal on the propagation terminal. The circuit 30 includes, to do this, an operational amplifier AOP mounted as a follower in order to generate the postsynaptic read signal applied to the propagation terminal. The non-inverting input of the amplifier AOP is at a voltage V_{BL}_{_{read}} such that V_{DD}−V_{BL}_{_{read}}=V_{read}. The output thereof is connected via the switchable connector S_{read} to the gate of a PMOS transistor P of which the source is connected to the Bit-Line BL and returned to the inverting input of the amplifier AOP and of which the drain is connected to the accumulator Cm. Thus during the read, it is possible to maintain a postsynaptic read signal that has the voltage V_{BL}_{_{read}} on the Bit-Line BL while still integrating the synaptic current in the accumulator Cm. The amplifier AOP can be controlled, for example by the command Cmd_{read}, in such a way as to not consume during write operations.

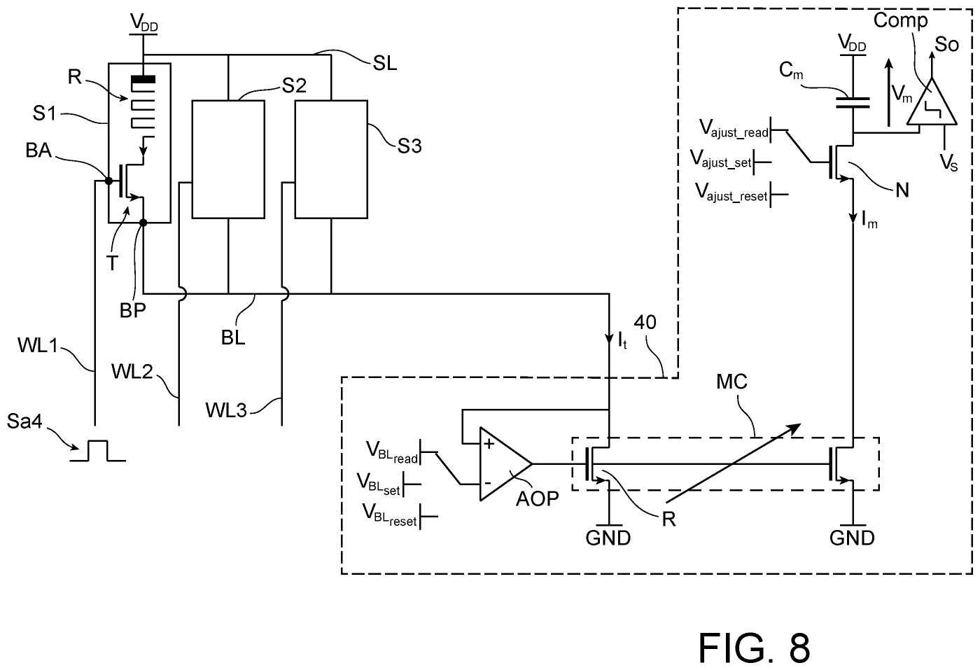

In another embodiment shown in FIG. 8, the presynaptic action signal Sa4 has a single spike. The circuit 40 can then carry out a read only operation or simultaneously carry out a write operation and a read operation. The circuit 40 is for this configured, when the presynaptic action signal Sa4 is applied on the activation terminal, to impose a read voltage on the synapse by applying a postsynaptic read signal V_{BL}_{_{read}} on the propagation terminal or to impose a write voltage on the synapse by applying the postsynaptic action signal, at V_{BL} set or V_{BL}_{ᵣₑₛₑₜ}, on the propagation terminal.

The circuit 30 includes an operational amplifier AOP mounted as a follower in order to adjust the voltage of the Bit-Line by selectively generating the postsynaptic read signal or the postsynaptic action signal. The inverting input of the amplifier AOP is at one of the voltages V_{BL}_{_{read}}, V_{BL}_{ₛₑₜ} or V_{BL}_{ᵣₑₛₑₜ}. The output thereof is connected to the gate of a NMOS transistor R of which the drain is connected to the Bit-Line BL and returned to the non-inverting input of the amplifier AOP and of which the source is connected to the ground GND.

The current It that passes through the synapse S1 depends on the value of the resistor R as well as on the voltage on the Bit-Line. This current therefore depends on the type of Set, Reset or Read operation. In order to be able to integrate the synaptic current in the accumulator Cm although a write operation is implemented, the circuit 40 comprises a current step-down device MC that is inserted between the propagation terminal and the accumulator Cm and which is activated when the circuit imposes a conductance modification voltage on the synapse. As shown in FIG. 8, this current step-down device MC can have the form of a current mirror of which it is possible to vary the transformation ratio in such a way that the current Im travelling through the accumulator Cm is independent of the type of access. Taking again the example of a supply voltage V_{DD}=1.8 V and access voltages Vₛₑₜ=1.6 V, Vᵣₑₛₑₜ=1.2 V and V_{read}=0.4 V, there is therefore Vₛₑₜ=4*V_{read} and Vᵣₑₛₑₜ=3*V_{read}. The current step-down device is then configured so that Im=It/4 during a Set write operation and so that Im=It/3 during a Reset write operation.

In the circuit of FIG. 8, the transistor R used for the adjustment of the voltage of the Bit-Line is also made use of in the current mirror MC. These two functions can however be separated.

It is moreover possible to have recourse to a transistor N between the current step-down device MC and the accumulator Cm. Different gate polarisations V_{ajust_read}, V_{ajust_set}, V_{ajust_reset} can be selectively applied to this transistor N in order to counterbalance differences in polarisation at the level of the current step-down device MC according to the access carried out and thus render the current Im even more independent of the type of access.

The invention is not limited to the circuit described hereinabove, but extends to a neuromorphic chip comprising a plurality of resistive memory synapses arranged in a network with transversal lines and columns. Each synapse is for example of the 1T1R cell or 1S1R cell type. Each synapse has an activation terminal and a propagation terminal, with the activation terminals of the synapses of the same line being connected together, with the propagation terminals of the synapses of the same column being connected together and connected to a synaptic integration circuit such as described hereinabove.

What is claimed is:

1. A synaptic integration circuit for a neuromorphic chip comprising a resistive memory synapse which has an activation terminal and a propagation terminal,
said circuit comprising:
an accumulator of a synaptic output signal received from the propagation terminal and which depends on a resistance of the resistive memory synapse,
a comparator configured to emit a postsynaptic spike in case the accumulated synaptic output signal crosses a threshold, and
a control unit configured, when a presynaptic action signal is applied on the activation terminal, to impose a conductance modification voltage on the synapse by controlling the application of a postsynaptic action signal on the propagation terminal.

2. The synaptic integration circuit according to claim 1, comprising a switchable connector configured to connect the accumulator to the propagation terminal when a read pulse of the presynaptic action signal is applied on the activation terminal.

3. The synaptic integration circuit according to claim 2, wherein the switchable connector is configured to disconnect the accumulator from the propagation terminal when a write pulse of the presynaptic action signal is applied on the activation terminal.

4. The synaptic integration circuit according to claim 2, wherein the control unit is furthermore configured, when the read pulse of the presynaptic action signal is applied on the activation terminal, to impose a read voltage on the synapse by controlling the application of a postsynaptic read signal on the propagation terminal.

5. The synaptic integration circuit according to claim 4, wherein the postsynaptic read signal is generated by an operational amplifier mounted as a follower.

6. The synaptic integration circuit according to claim 1, wherein the control unit is furthermore configured, when the presynaptic action signal is applied on the activation terminal, to impose a read voltage on the synapse by controlling the application of a postsynaptic read signal on the propagation terminal.

7. The synaptic integration circuit according to claim 6, wherein the postsynaptic read signal and the postsynaptic action signal are selectively generated by comprising an operational amplifier mounted as a follower.

8. The synaptic integration circuit according to claim 6, further comprising a current step-down device that is inserted between the propagation terminal and the accumulator and which is activated when the control unit imposes the conductance modification voltage on the synapse.

9. The synaptic integration circuit according to claim 1, wherein the control unit is configured to control the application of the postsynaptic action signal on the propagation terminal in accordance with a learning logic of the spike-driven synaptic plasticity type.

10. The Synaptic integration circuit according to claim 1, wherein the postsynaptic action signal is one of a potentiation signal and of a depression signal.

11. A neuromorphic chip comprising a plurality of resistive memory synapses arranged in a network with transversal lines and columns, with each resistive memory synapse having an activation terminal and a propagation terminal, with the activation terminals of the resistive memory synapses of the same line being connected together, with the propagation terminals of the resistive memory synapses of the same column being connected together and connected to a synaptic integration circuit according to claim 1.

12. The neuromorphic chip according to claim 11, wherein each resistive memory synapse consists of a 1T1R cell or a 1S1R cell.
